(19) United States
(12) Patent Application Publication
(10) Pub. No.: US 2009/0283855 A1
(43) Pub. Date: Nov. 19, 2009

(54) SEMICONDUCTOR DEVICE AND PROCESS FOR MANUFACTURING THE SAME

(76) Inventors: Hidenori IWADATE, Hyogo (JP); Masaoki KAJIYAMA, Osaka (JP)

Correspondence Address: MCDERMOTT WILL & EMERY LLP, 600 13TH STREET, NW, WASHINGTON, DC, 20005-3096, US

(21) Appl. No.: 12/467,708

(22) Filed: May 18, 2009

(30) Foreign Application Priority Data
May 19, 2008 (JP) 2008-130412

(51) Int. Cl. H01L 29/86; H01L 21/02

(52) U.S. Cl. 257/531; 438/381; 257/E29.325; 257/E21.022

(57) ABSTRACT

An inductor having a helicoidal shape is provided on an insulation film formed on a semiconductor substrate. A conductive thin layer (a plating layer) is provided on a surface of the inductor. A conductivity of the conductive thin layer is higher than that of the inductor. According to the constitution, a Q value can be improved, and a large volume of current can be flowed.

### BACKGROUND OF THE INVENTION

1. Field of the Invention

The present invention relates to a semiconductor device wherein an inductor having a helicoidal shape is provided on an insulation film formed on a semiconductor substrate and a process for manufacturing the semiconductor device.

2. Description of the Related Art

In recent years, with the wide dispersion of terminal devices for mobile communications, examples of which are PHS (Personal Handy-Phone System) and mobile telephones, there is an increasing demand for cost reduction in high frequency circuits used in these devices. To meet the demand for the cost reduction of the high frequency circuits, high frequency circuits formed by bipolar, CMOS or Bi-CMOS transistors are adopted in these terminal devices. However, the high frequency circuits thus constituted require passive components such as inductors, capacitances and resistors as indispensable components for impedance matching, and all of these components need to be installed on a single chip to reduce costs.

Of the passive components, resistors and capacitances can be relatively easily formed on the semiconductor element. Therefore, the formation of inductors becomes important in the manufacturing of a high frequency circuit. An inductor, an indispensable component of a high frequency circuit, is required to have such characteristics as, first and foremost, a high Q value (quality factor); secondary, a low loss; and thirdly, a high resonance frequency.

Although various types are so far proposed as the structure of an inductor which generates inductivity, a planar structure of an inductor where metal interconnection is formed on a plane in a helicoidal shape is generally adopted.

A Q value is a characteristic contributing to the reduction of power consumption in a circuit and is a very important parameter. The Q value is determined by a value obtained by dividing an inductance value in a resonance frequency by a serial resistance value in, for example, a serial resonance LC circuit, and represented by the following formula 1).

Q=ωL/R 1)

In the formula 1), ω denotes 2nf, n denotes the ratio of the circumference of a circle to its diameter, f denotes a frequency, L denotes an inductance value, and R denotes a resistance value.

FIG. 7 illustrates the Q characteristic of a commonly used inductor. As illustrated in FIG. 7, a capacitance loss occurs due to capacitance coupling between the inductor and the substrate as the frequency increases, and the Q value is thereby decreased in a high frequency band. As a result, the Q value shows a waveform shape protruding upward.

According to the formula 1) described earlier, effective ways to increase the Q value are to reduce the serial resistance component of the inductor and control the capacitance loss.

When there is a current flow in a conductor, an inductive magnetic field is accordingly generated. As a result, electromotive force is generated in the direction that prevents the current flow from changing. As the current flow is closer to the center of the conductor, its flux linkage is larger and its back electromotive force is also larger, and therefore, its current density is lessened. Accordingly, there is a large concentration of current flow on a peripheral portion of the conductor, which is called a conductor skin effect. In the case of an alternating current, an effective cross-sectional area is decreased by a conductor skin effect in comparison to a physical cross-sectional area, and an effective resistance value is thereby increased.

As described earlier, the current in the conductor decreases as the distance from its surface increases. A point at which a value of the current is 1/e as large as that of the surface is called a conductor skin depth. The conductor skin depth is represented by the following formula 2).

d=√(2/ωμσ) 2)

In the formula 2), d denotes the skin depth, ω denotes 2nf, π denotes the ratio of the circumference of a circle to its diameter, f denotes a frequency, μ denotes a magnetic permeability, and σ denotes an electric conductivity.

In the case of aluminum, for example, the conductor skin depth is 0.8 μm at 10 GHz. At such an operation frequency, the increase of a thickness of the conductor does not contribute to the reduction of the effective resistance value. Therefore, in the case of an alternating current, the conductor skin depth d is smaller as the frequency band is higher, and the alternating current flows near the extremely surface of the conductor, which results in the increase of the effective resistance value. Therefore, the effective resistance value is increased as the operation frequency band is higher, and the Q value is thereby lowered. As a result, the inductance characteristics are deteriorated.

In order to solve the problem described above, an inductor having such a structure that is illustrated in 2003-209183 of the Japanese Patent Applications Laid-Open (hereinafter, referred to as a conventional example) was proposed. Referring to FIGS. 8 and 9, the structure according to the conventional example is described. FIG. 8 is a plain view of a conventional inductor having a helicoidal shape, and FIG. 9 is a cross sectional view of the conventional helicoidal inductor of FIG. 8 taken along the line B-B′.

In FIG. 8, an inductor 9 has a helicoidal shape. As illustrated in FIG. 9, a plurality of grooves 11 are provided in a interconnection portion of the inductor 9, and a cross section thereof has a comb shape. In the inductor according to the conventional example having such a shape, a peripheral length of the sectional surface in the interconnection portion is increased, and the increase of the resistance value resulting from the conductor skin effect is controlled, which results in the reduction of the effective resistance value. As a result, the Q value characteristic of the inductor 9 is improved.

The conventional example, however, is disadvantageous in that it is difficult to flow a large volume of current in the inductor 9. In high frequency circuits provided in a terminal device for mobile communications typified by a mobile telephone, particularly in a driver amplifier in an output stage, power is increased as a signal frequency is higher, further, it is necessary to flow a few tens of mA of current, at most, in order to improve distortion. However, in the conventional example wherein the plurality of grooves 11 are provided in the interconnection portion and the cross section thereof has a comb shape, a cross-sectional area is inevitably small. Moreover, in the case of forming inductor interconnection using CMP (Chemical Mechanical Polishing) equipment in a process for manufacturing the conductor thus constituted, a interconnection thickness near the center of the bottom portion of the cross section becomes small under the influence of dishing in the case of a large interconnection width (at least 20 μm). As a result, the serial resistance component is increased. Therefore, in this manufacturing process, the interconnection width cannot be increased when the influence described above is taken into consideration, and an allowable current volume flowing in the inductor 9 is inevitably small.

### SUMMARY OF THE INVENTION

Therefore, a main object of the present invention is to improve a Q value of a inductor by reducing its effective resistance value in a high frequency band and provide an inductor wherein a large volume of current can be flowed as well as a process for manufacturing the inductor.

In order to achieve the main object, a semiconductor device according to the present invention comprises

an insulation film provided on a semiconductor substrate;

an inductor provided in a helicoidal shape on the insulation film; and

a conductive thin layer provided on a surface of the inductor, wherein

the conductive thin layer has a higher conductivity than the inductor.

According to the present invention, in a high frequency band, a high frequency current flowing near the extremely surface of a conductor due to the conductor skin effect flows through a conductive thin layer whose conductivity is higher than that of the inductor. As a result, an effective resistance value of the inductor is reduced, and a high Q value can be thereby obtained. The constitution according to the present invention eliminates the necessity to perform a dual-damascene process, which makes it unnecessary to take into account a dishing problem. Therefore, an interconnection width of the inductor can be increased. As a result, a cross-sectional area of the inductor is not reduced, and a large volume of current can be flowed in the inductor.

A semiconductor device manufacturing process according to the present invention is a process for manufacturing a semiconductor device comprising an inductor formed in a helicoidal shape, including:

a step of forming an insulation film on a semiconductor substrate;

a step of forming the inductor and a conductive pad each made up by a first conductor on the insulation film at the same time; and

a step of forming a conductive thin layer made up by a second conductor so as to selectively cover the inductor and the conductive pad, wherein

the second conductor has a higher conductivity than the first conductor.

According to the manufacturing process, the restriction on the interconnection width due to the dishing problem in a CMP device can be removed since it is made unnecessary to use the CMP device in the formation of the inductor and the conductive pad. Therefore, the interconnection width of the inductor can be increased, and the thickness of the inductor can be accordingly increased. As a result, an inductor in which a large volume of current can be flowed can be provided.

The constitution is further advantageous in that the conductive pad and the inductor are formed at the same time, and the conductive thin layer is formed on the inductor in parallel with the formation of the conductive thin layer on the conducive pad. Therefore, the increase of the effective resistance value in a high frequency band can be easily controlled without any additional steps. As a result, an inductor having superior characteristics in a high frequency band can be manufactured with lower costs.

According to the semiconductor device and the semiconductor device manufacturing process provided by the present invention, since the conductive thin layer (a plating layer or the like) whose conductivity is higher than that of the metal constituting an inductor is formed on the upper and side surfaces of the inductor, the effective resistance component can be prevented from increasing even if there is a large concentration of current flow near the inductor surface due to the conductor skin effect in a high frequency band. Moreover, the increase of the effective resistance component is prevented by the formation of the conductive thin layer (a plating layer or the like), and the shape of the inductor (a cross sectional shape in particular) is not altered at all. Therefore, a large volume of current can be flowed without causing any problems to the inductor. As so far described, the present invention can realize an inductor having a high Q value.

According to the semiconductor device manufacturing process provided by the present invention, because the conductive thin layer is formed on the inductor and the conductive pad at the same time, the increase of the effective resistance value in a high frequency band can be easily controlled without any additional steps, and an inductor having superior characteristics in a high frequency band can be provided at a low cost.

The semiconductor device and the semiconductor device manufacturing process according to the present invention are useful as an integrated circuit designed for a high frequency band, comprising an inductor of which the improvement of a high frequency operation is demanded.

### BRIEF DESCRIPTION OF THE DRAWINGS

These and other objects of the invention will become clear by the following description of preferred embodiments of the invention and be specified in the claims attached hereto. A number of benefits not recited in this specification will come to the attention of the skilled in the art upon the implementation of the present invention.

FIG. 1 is a plain view of an inductor according to a preferred embodiment 1 of the present invention.

FIG. 2 is a cross sectional view of the inductor according to the preferred embodiment 1 of FIG. 1 taken along the line A-A′.

FIGS. 3A-3C are cross sectional views of respective steps in an inductor manufacturing process according to a preferred embodiment 2 of the present invention.

FIGS. 4A-4C are cross sectional views of respective steps in the first half of an inductor manufacturing process according to a preferred embodiment 3 of the present invention.

FIGS. 5A-5C are cross sectional views of respective steps in the latter half of the inductor manufacturing process according to the preferred embodiment 3.

FIGS. 6A-6C are cross sectional views of respective steps in the latter half of an inductor manufacturing process according to a modified embodiment of the preferred embodiment 3.

FIG. 7 is a correlation chart between a Q value and a frequency of the inductor.

FIG. 8 is a plain view of a conventional inductor.

FIG. 9 is a cross sectional view of the conventional inductor of FIG. 8 taken along the line B-B′.

### DETAILED DESCRIPTION OF THE INVENTION

Hereinafter, preferred embodiments of the present invention are described referring to the drawings.

### Preferred Embodiment 1

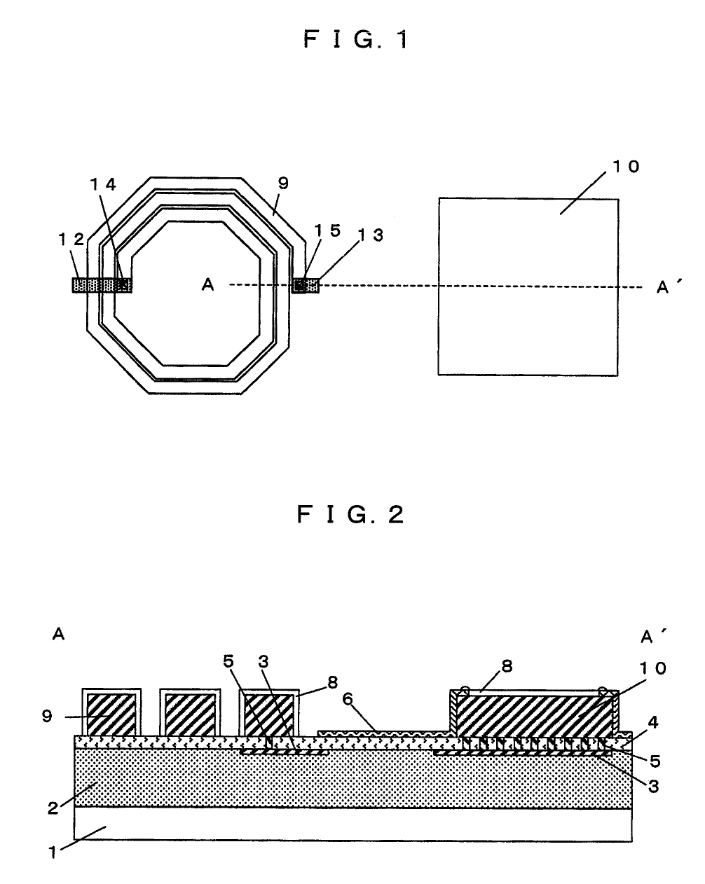

FIG. 1 is a plain view of a semiconductor device comprising an inductor having a helicoidal shape according to a preferred embodiment 1 of the present invention, and FIG. 2 is a cross sectional view of FIG. 1 taken along the line A-A′. In FIG. 1, 9 denotes an inductor, 10 denotes a conductive pad, 12 denotes drawing interconnection in an inner terminal of the inductor, 13 denotes drawing interconnection in an outer terminal of the inductor, 14 denotes a drawing via hole in the inner terminal of the inductor, and 15 denotes a drawing via hole in the outer terminal of the inductor. In FIG. 2, 1 denotes a semiconductor substrate, 2 denotes an inter-layer insulation film, 3 denotes lower interconnection, 4 denotes an insulation film, 5 denotes a via hole, 6 denotes a protective film which covers the insulation film 4, 8 denotes a plating layer which is an example of conductive thin layers, 9 denotes an inductor, and 10 denotes a conductive pad.

The insulation film 4 is formed on the semiconductor substrate 1, and the conductive pad 10 and the inductor 9 are formed on the insulation film 4. A metal layer made of the same metal (for example, made of aluminum alloy) constitutes each of the conductive pad 10 and the inductor 9, and the conductive pad 10 and the inductor 9 respectively have a film thickness of approximately 500-2,500 nm. Each of the conductive pad 10 and the inductor 9 is covered with the plating layer 8. The plating layer 8 is made of, for example, gold. The plating layer 8 is provided selectively on the upper surface of the conductive pad 10. The plating layer 8 is provided on the inductor 9, selectively on the upper and side surfaces except for the bottom surface thereof. The plating layer 8 is made of a material having a conductivity higher than that of the conductive pad 10 and that of the inductor 9. In the case where the conductive pad 10 and the inductor 9 are made of aluminum alloy, the plating layer 8 may be made of gold, or made of such a material as silver or copper. The plating layer 8 is formed in a film thickness of approximately 1,000 nm. The protective film 6 covers the insulation film 4 except the portion where the conductive pad 10 is formed.

In the semiconductor device according to the preferred embodiment 1, since the inductor 9 is covered with the plating layer 8, a high frequency current flows in the plating layer 8 which has a higher conductivity than the inductor 9 and the conductive pad 10 even if there is a large concentration of current flow near the inductor surface due to a conductor skin effect in a high frequency band. Accordingly, the effective resistance value can be prevented from increasing. Moreover, the shape of the inductor 9 is not altered at all (particularly, the cross sectional shape thereof) in order to prevent the effective resistance value from increasing; therefore, an interconnection width of the inductor 9 can be kept as thick as possible. As a result, a large volume of current can be flowed in the inductor 9. Thus, according to the preferred embodiment 1, an inductor structure, wherein the improvement of a Q value and a large volume of current flow can be realized, can be provided.

### Preferred Embodiment 2

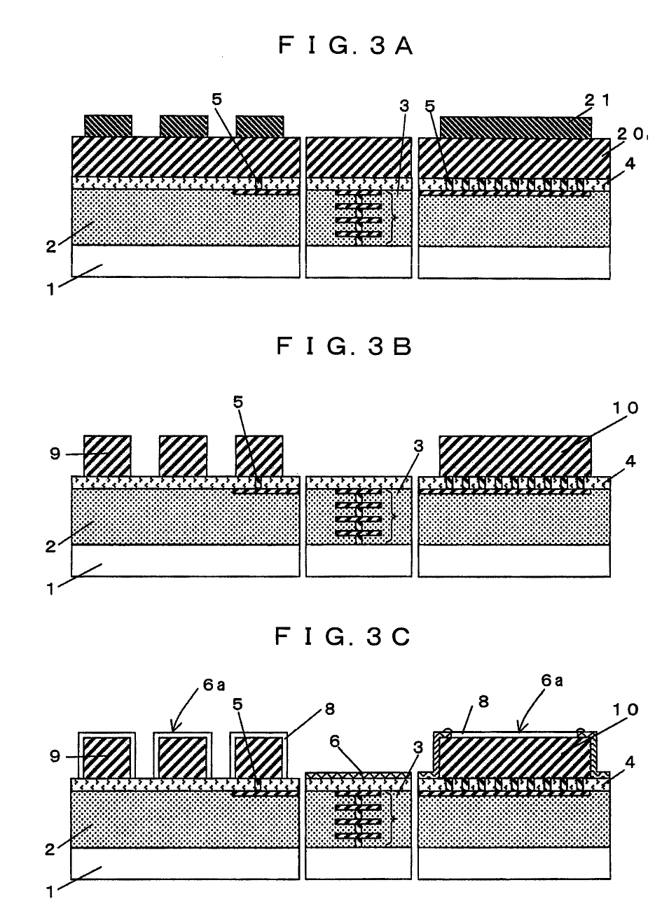

FIG. 3 are cross sectional views of respective steps in a process for manufacturing an inductor having a helicoidal shape according to a preferred embodiment 2 of the present invention. In FIGS. 3, 1 denotes a semiconductor substrate, 2 denotes an inter-layer insulation film, 3 denotes lower interconnection, 4 denotes an insulation film, 5 denotes a via hole, 6 denotes a protective film, 8 denotes a plating layer which is an example of conductive thin layers, 9 denotes an inductor, and 10 denotes a conductive pad.

First, the semiconductor substrate 1 provided with the lower interconnection (constituting multilayered interconnection) 3 in the inter-layer insulation film 2 is prepared, and the insulation film 4 is formed on the semiconductor substrate 1. Then, the via holes 5, which will provide an inter-layer connection to the inductor 9 and the conductive pad 10, are formed in the insulation film 4 (see FIG. 3A). Next, a metal film 20 made of aluminum alloy or the like, which is an example of a first conductor, is deposited on the insulation film 4, and a photo resist pattern 21 is thereafter formed on the metal film 20. The photo resist pattern 21 has a shape appropriate to the inductor 9 and the conductive pad 10. Then, a dry etching process, in which the photo resist pattern 21 is used as a mask, is performed, so that the metal film 20 is selectively removed. Thus, the conductive pad 10 and the inductor 9 each made up by the first conductor are formed at the same time on the insulation film 4 (see FIG. 3B). After the formation of the conductive pad 10 and the inductor 9, the photo resist pattern 21 is removed.

Next, the protective film 6 is formed on the insulation film 4 so as to cover the conductive pad 10 and the inductor 9. The protective film 6 is made of an oxide film material or a resin material such as polyimide or polybenzoxazole (PBO). Further, openings 6a are formed in the protective film 6. The openings 6a are formed selectively in the upper surface of the conductive pad 10 and the peripheral surface of the inductor 9 (the side and upper surfaces except the bottom surface) (see FIG. 3C).

Next, with the protective film 6 used as a mask, the plating layer 8 made of gold or the like, which is an example of a second conductor, is formed selectively on the upper surface of the conductive pad 10 and the peripheral surface of the inductor 9 exposed by the openings 6a. The plating layer 8 is formed on the upper surface of the conductive pad 10 and the peripheral surface of the inductor 9 at the same time by a means of an electroless plating method. The material of the plating layer 8 (second conductor) has a higher conductivity than the materials of the conductive pad 10 and the inductor 9 (first conductor). In the case where the conductive pad 10 and the inductor 9 are made of aluminum alloy, the plating layer 8 is made of, for example, gold. The plating layer 8 is formed in a film thickness of approximately 1,000 nm.

According to the preferred embodiment 2, since it is unnecessary to use a CMP device in the formation of the conductive pad 10 and the inductor 9, the restriction on the interconnection width of the inductor 9 due to the dishing problem in the CMP device can be eliminated, and the inductor width can be thickened. Moreover, the conductive pad 10 and the inductor 9 are formed at the same time, and the plating layer 8 is formed on the conductive pad 10 and the inductor 9 at the same time in the preferred embodiment 2. As a result, an inductor capable of reducing the effective resistance value in a high frequency band can be easily manufactured without any additional steps.

### Preferred Embodiment 3

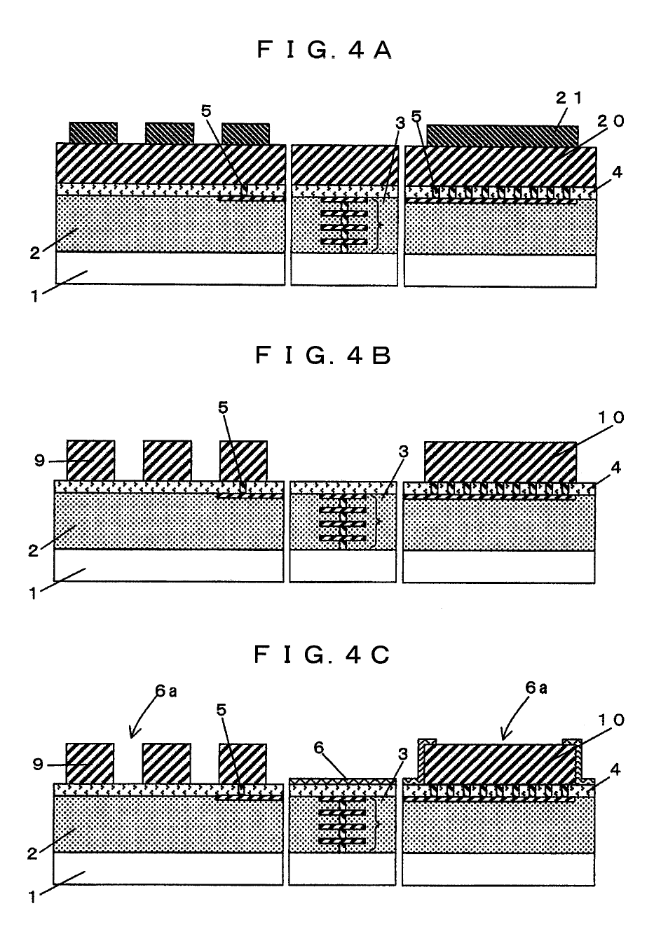

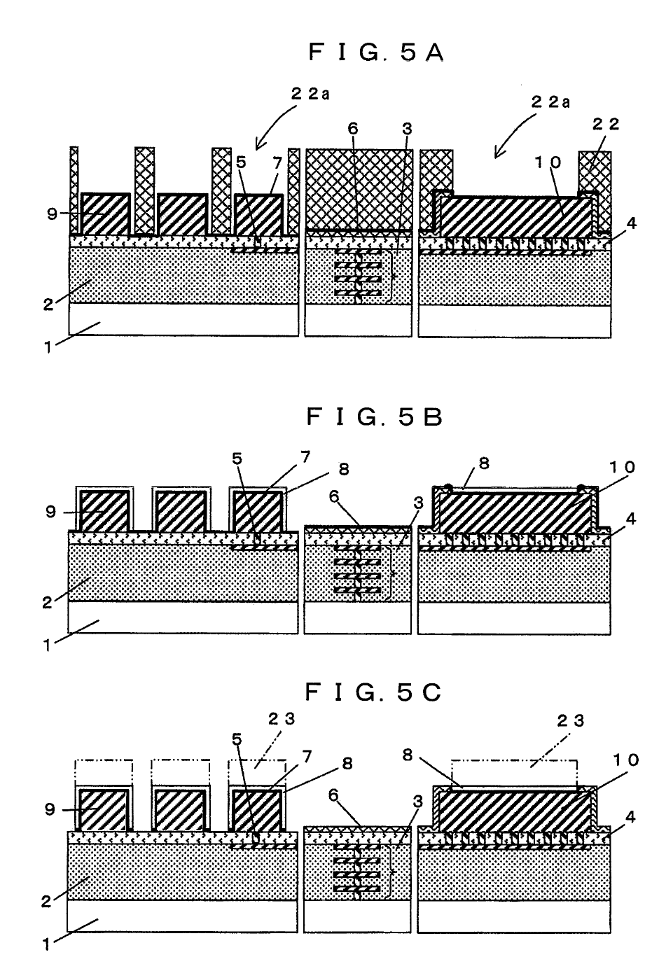

FIGS. 4 and 5 are cross sectional views of respective steps in a process for manufacturing an inductor having a helicoidal shape according to a preferred embodiment 3 of the present invention. In FIGS. 4 and 5, 1 denotes a semiconductor substrate, 2 denotes an inter-layer insulation film, 3 denotes lower interconnection, 4 denotes an insulation film, 5 denotes a via hole, 6 denotes a protective film, 7 denotes a metal thin film, 8 denotes a plating layer which is an example of conductive thin layers, 9 denotes an inductor, and 10 denotes a conductive pad.

First, the semiconductor substrate 1 provided with the lower interconnection (constituting multilayered interconnection) 3 in the inter-layer insulation film 2 is prepared, and the insulation film 4 is formed on the semiconductor substrate 1. Then, the via holes 5, which provides an inter-layer connection in the inductor 9 and the conductive pad 10, are formed in the insulation film 4 (see FIG. 4A). Next, a metal film 20 made of aluminum alloy or the like, which is an example of a first conductor, is deposited on the insulation film 4, and a photo resist pattern 21 having a shape appropriate to the inductor 9 and the conductive pad 10 is thereafter formed on the metal film 20. Then, a dry etching process, in which the photo resist pattern 21 is used as a mask, is performed, so that the metal film 20 is selectively removed. Thus, the conductive pad 10 and the inductor 9 each formed by the first conductor are provided at the same time on the insulation film 4 (see FIG. 4B). After the formation of the conductive pad 10 and the inductor 9, the photo resist pattern 21 is removed.

Next, the protective film 6 is formed on the insulation film 4 so as to cover the conductive pad 10 and the inductor 9. The protective film 6 is made of an oxide film material or a resin material such as polyimide or polybenzoxazole (PBO) Further, second openings 6a are formed in the protective film 6. The openings 6a are formed selectively in the upper surface of the conductive pad 10 and the peripheral surface of the inductor 9 (the side and upper surfaces except the bottom surface) (see FIG. 4C).

Then, the metal thin film 7 is formed so as to cover the protective film 6 and the second openings 6a. The metal thin film 7 is formed by sputtering titanium and gold each in a film thickness of approximately 200-400 nm. This metal thin film 7 serves as a plating electrode in an electroplating process subsequently performed (see FIG. 5A).

A resist film is formed on the metal thin film 7, and first openings 22a are then formed in the resist film, so that the resist film constitutes a first photo resist pattern 22. The first openings 22a are formed on the upper surface of the conductive pad 10 and the portion where the inductor 9 is formed. Then, the electroplating process is performed with the metal thin film 7 used as the plating electrode, so that the plating layer 8 is formed selectively on the first openings 22a of the first photo resist pattern 22 (the upper surface of the conductive pad 10 and the portion where the inductor 9 is formed) (see FIG. 5B). The plating layer 8 is made of, for example, gold which is an example of a second conductor. After the formation of the plating layer 8, the first photo resist pattern 22 is removed.

The metal thin film 7 (serving as the electrode in the electroplating), except that of the upper surface of the conductive pad 10 and that of the portion where the inductor 9 is formed, is etched to be removed. In the removal of the metal thin film 7, for example, a mixture solution containing I₂/KI/H₂O/CH₃COOH and H₂O₂ are used. In the removal of the metal thin film 7, the plating layer 8 is also etched at the same time. However, ultimately, the metal thin film 7 is selectively removed with the plating layer 8 serving as a mask because the plating layer 8 is thicker than the metal thin film 7 (see FIG. 5C).

According to the preferred embodiment 3, since it is unnecessary to use a CMP device in the formation of the conductive pad 10 and the inductor 9, the restriction on the interconnection width of the inductor 9 due to the dishing problem in the CMP device can be eliminated, and the inductor width can be thickened. Moreover, the conductive pad 10 and the inductor 9 are formed at the same time, and the plating layer 8 is formed on the conductive pad 10 and the inductor 9 at the same time in the preferred embodiment 3. As a result, an inductor capable of reducing the effective resistance value in a high frequency band can be easily manufactured without any additional steps.

### Modified Embodiment of the Preferred Embodiment 3

In the case where the plating layer 8 is thin or the film thickness of the plating layer 8 needs to be controlled in the preferred embodiment 3, a second photo resist pattern 23 may be formed as illustrated by imaginary lines in FIG. 5C and then the metal thin film 7 may be removed with the second photo resist pattern 23 used a mask. In this case, the photo resist pattern 23 is formed so as to cover selectively the portion where the plating layer 8 is formed.

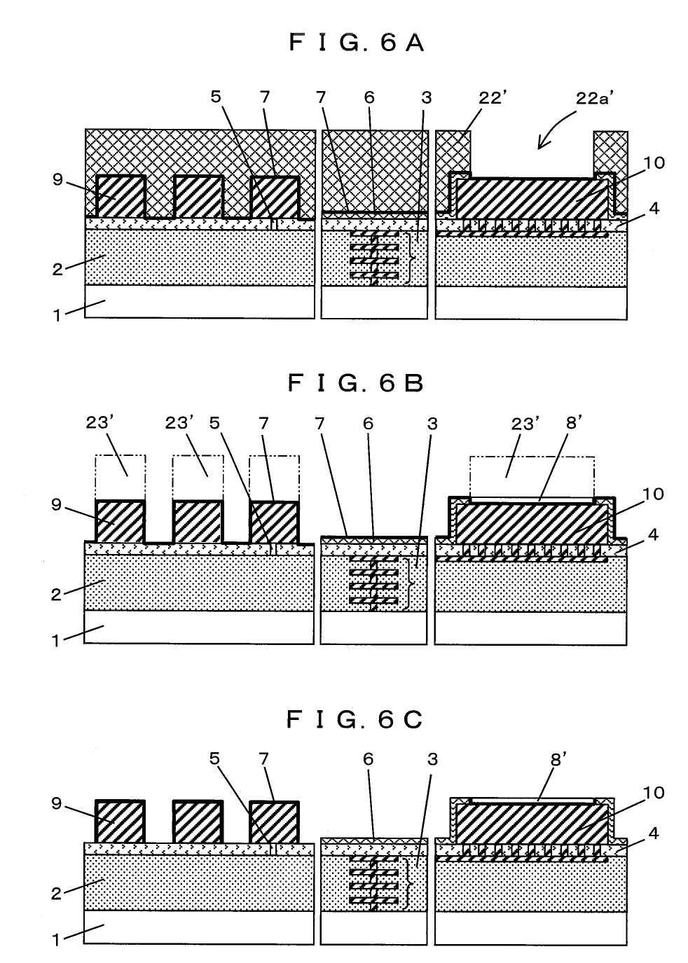

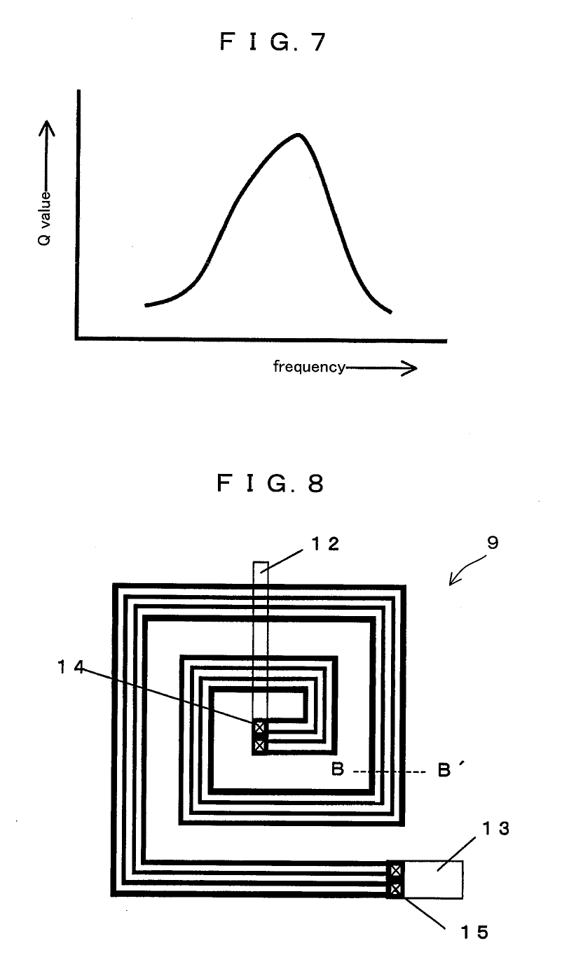

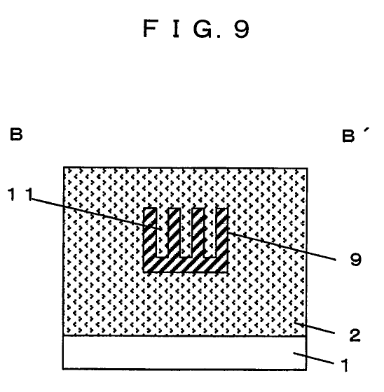

In the case where the conductor skin effect can be sufficiently obtained by the film thickness of the metal thin film 7 serving as the electrode for the electroplating depending on an operation frequency band, the metal thin film 7 alone may be formed on the inductor portion, while the formation of the plating layer 8 thereon is omitted. In this case, the semiconductor device is manufactured as follows. As illustrated in FIG. 6A, a first photo resist pattern 22′ having a first opening 22a′, which is formed to reach the conducive pad 10 alone, is formed on the metal thin film 7 in place of the first photo resist pattern 22. Then, the electroplating is performed with the first photo resist pattern 22′ used as a mask, so that a plating layer 8′ is formed selectively on the conductive pad 10. After the formation of the plating layer 8′, the first photo resist pattern 22′ is removed as illustrated in FIG. 6B, and a second photo resist pattern 23′, which covers selectively the inductor 9 and the plating layer 8′, is formed. Then, with the second photo resist pattern 23′ used as a mask, the metal thin film 7 is etched to be selectively removed except that of the portion where the inductor 9 and that of the plating layer 8′ are formed, as illustrated in FIG. 6C.

The electroless plating process may be adopted in the formation of the plating layers 8 and 8′. The plating layers 8 and 8′ may be made of copper or the like. The preferred embodiments 2 and 3 of the present invention do not impose limitation on any manufacturing steps of a lower interconnection layer and others except the steps described so far. Moreover, it is needless to say that any of the preferred embodiments do not impose limitation on the specification and manufacturing process of the substrate, materials of each layer, film thicknesses, formation conditions and the like.

While there has been described what is at present considered to be preferred embodiments of this invention, it will be understood that various modifications may be made therein, and it is intended to cover in the appended claims all such modifications as fall within the true spirit and scope of this invention.

What is claimed is:

1. A semiconductor comprising:
an insulation film provided on a semiconductor substrate;
an inductor provided in a helicoidal shape on the insulation film; and
a conductive thin layer provided on a surface of the inductor, wherein
the conductive thin layer has a higher conductivity than the inductor.

2. The semiconductor device as claimed in claim 1, wherein
the conductive thin layer is a plating layer.

3. The semiconductor device as claimed in claim 1, further comprising a conductive pad on the insulation film, wherein
the conductive thin layer is provided on surfaces of the inductor and the conductive pad, and the conductive thin layer has a higher conductivity than the inductor and the conductive pad.

4. The semiconductor device as claimed in claim 1, wherein
the conductive thin layer is provided on the peripheral surface of the inductor except the bottom surface thereof and the upper surface of the conductive pad.

5. The semiconductor device as claimed in claim 1, wherein
a metal layer made of the same material constitutes each of the inductor and the conductive pad.

6. The semiconductor device as claimed in claim 3, wherein
the insulation film is covered with a protective film except the portion where the conducive pad is formed.

7. The semiconductor device as claimed in claim 3, wherein
a main material of the inductor and the conductive pad is aluminum, and a main material of the conductive thin layer is gold.

8. A process for manufacturing a semiconductor device comprising an inductor formed in a helicoidal shape, including:
a step of forming an insulation film on a semiconductor substrate;
a step of forming the inductor and a conductive pad each made up by a first conductor on the insulation film at the same time; and
a step of forming a conductive thin layer made up by a second conductor so as to selectively cover the inductor and the conductive pad, wherein
the second conductor has a higher conductivity than the first conductor.

9. The process for manufacturing a semiconductor device as claimed in claim 8, wherein
the first conductor is metal.

10. The process for manufacturing a semiconductor device as claimed in claim 9, wherein
the second conductor is metal, and the conductive thin layer is a plating layer.

11. The process for manufacturing a semiconductor device as claimed in claim 10, wherein
the step of forming the conductive thin layer made up by the plating layer is performed by means of electroless plating.

12. The process for manufacturing a semiconductor device as claimed in claim 10, wherein
the step of forming the conductive thin layer made up by the plating layer further includes
a step of forming a metal thin film selectively on the inductor and the conductive pad;
a step of forming a first photo resist pattern having first openings appropriate to the portion where the inductor is formed and the portion where the conductive pad is formed on the metal thin film, and thereafter forming a plating layer by performing electroplating using the first photo resist pattern as a mask and the metal thin film as an electrode; and
a step of removing the first photo resist pattern and thereafter etching and removing the metal thin film remaining below the first photo resist pattern.

13. The process for manufacturing a semiconductor device as claimed in claim 12, wherein
the step of removing the metal thin film is performed after a second photo resist pattern is formed so as to cover the inductor and the conductive pad.

14. The process for manufacturing a semiconductor device as claimed in claim 12, further including, before the step of forming the metal thin film is performed,
a step of forming a protective film on the insulation film including the portion where the inductor is formed and the portion where the conductive pad is formed; and
a step of forming second openings in the portion where the inductor is formed and the portion where the conductive pad is formed in the protective film.

15. A process for manufacturing a semiconductor device comprising an inductor formed in a helicoidal shape, including:
a step of forming an insulation film on a semiconductor substrate;
a step of forming the inductor and a conductive pad each made up by a first conductor on the insulation film at the same time; and
a step of forming a metal thin film made up by a second conductor having a higher conductivity higher than the first conductor on the inductor and the conducive pad; and
a step of forming a first photo resist pattern having an opening on the conductive pad on the metal thin film;
a step of selectively forming a plating layer on the conductive pad by performing electroplating for which the first photo resist pattern is used as a mask and the metal thin film is used as an electrode;
a step of removing the first photo resist pattern and thereafter forming a second photo resist pattern selectively covering the inductor; and
a step of selectively preserving the metal thin film on the inductor and etching and removing the reminder of the metal thin film, with the second photo resist pattern used as a mask.

16. The process for manufacturing a semiconductor device as claimed in claim 12, wherein
a main material of the inductor and the conductive pad is aluminum, and
a main material of the plating layer and the metal thin film is gold.

17. The process for manufacturing a semiconductor device as claimed in claim 15, wherein
a main material of the inductor and the conductive pad is aluminum, and
a main material of the plating layer and the metal thin film is gold.
